(19) United States
(12) Patent Application Publication
(10) Pub. No.: US 2013/0004681 A1
(43) Pub. Date: Jan. 3, 2013

(54) MINI BLOCKER PLATE WITH STANDOFF SPACERS

(75) Inventors: Alan Tso, San Jose, CA (US); Jeonghoon Oh, San Jose, CA (US); Yi Zheng, Sunnyvale, CA (US); Tom K. Cho, Los Altos, CA (US); Zheng Yuan, Cupertino, CA (US); Lin Zhang, San Jose, CA (US); Qunhua Wang, San Jose, CA (US); Robin L. Tiner, Santa Cruz, CA (US)

(73) Assignee: APPLIED MATERIALS, INC., Santa Clara, CA (US)

(21) Appl. No.: 13/174,690

(22) Filed: Jun. 30, 2011

(51) Int. Cl. C23C 16/50; F24H 9/12

(52) U.S. Cl. 427/569; 138/37

(57) ABSTRACT

Embodiments of the present invention provide a plasma processing chamber having a mini blocker plate for delivering processing gas to a processing chamber and methods to use the mini blocker plate to improve uniformity. The blocker plate assembly comprising a mini blocker plate having a plurality of through holes, and two or more standoff spacers configured to position the mini blocker plate at a distance away from a blocker plate.

### BACKGROUND OF THE INVENTION

1. Field of the Invention

Embodiments of the present invention generally relate to a method and apparatus for processing substrates, such as solar panel substrates, flat panel substrates, or semiconductor substrates. More particularly, embodiments of the present invention relate to a mini blocker plate for delivering processing gas to a processing chamber and methods to use the same.

2. Description of the Related Art

Chemical vapor deposition (CVD) generally employed to deposit thin films on substrates, such as semiconductor substrates, solar panel substrates, and liquid crystal display (LCD) substrates. Chemical vapor deposition is generally accomplished by introducing a precursor gas into a vacuum chamber having a substrate disposed on a substrate support.

Uniformity is generally desired in the thin films deposited using CVD process. For example, an amorphous silicon film, such as microcrystalline silicon film or microcrystalline silicon film, or a polycrystalline silicon film is usually deposited using CVD on a flat panel for forming p-n junctions required in transistors or solar cells. The quality and uniformity of the amorphous silicon film or polycrystalline silicon film are important for commercial operation.

To achieve uniform gas flow and/or plasma density for plasma enhanced CVD process, the precursor gas is typically directed to a processing chamber from a gas inlet through an opening in a blocker plate to a volume above a distribution plate having a plurality of holes, and through the plurality of holes to a processing volume above the substrate disposed on the substrate support. However, the gas flow near the region corresponding to the opening in the blocker plate is usually lower than other regions using the state of the art blocker plate and distribution plate assembly causing the non-uniformity. The region in a solar device near the opening of the state of the art blocker plate also demonstrates low convertion efficiency.

Therefore, there is a need for processing chambers with improved uniformity in gas delivery.

### SUMMARY OF THE INVENTION

Embodiments of the present invention provide a plasma processing chamber having a mini blocker plate for delivering processing gas to a processing chamber and methods to use the mini blocker plate to improve uniformity.

One embodiment of the present invention provides a blocker plate assembly comprising a mini blocker plate having a first side and a second side, wherein a plurality of through holes are formed from the first side to the second side in a central region of the mini blocker plate, and two or more standoff spacers disposed on the first side of the mini blocker plate near an edge region of the mini blocker plate, wherein the mini blocker plate is configured to cover an inlet opening in a blocker plate, and the two or more standoff spacers are configured to position the first side of the mini blocker plate at a distance away from the blocker plate.

Another embodiment of the present invention provides an apparatus for delivering processing gas to a processing chamber comprising a blocker plate having an inlet opening near a central region, a distribution plate substantially parallel to the blocker plate, wherein the blocker plate and the distribution plate define a gas distribution volume therebetween, a first side of the distribution plate faces the blocker plate and a second side of the distribution plate faces a processing volume outside the distribution volume, and the distribution plate has a plurality of through holes connecting the gas distribution volume and the processing volume, and a mini blocker plate assembly disposed in the gas distribution volume over the inlet opening of the blocker plate, wherein the mini blocker plate assembly comprises a mini blocker plate having a first side and a second side, wherein a plurality of through holes are formed from the first side to the second side in a central region of the mini blocker plate, and the first side of the mini blocker plate faces the inlet opening of the blocker plate, and two or more standoff spacers disposed on the first side of the mini blocker plate near an edge region of the mini blocker plate, wherein the two or more standoff spacers position the first side of the mini blocker plate at a distance away from the blocker plate so that a gap is formed between the mini blocker plate and the blocker plate.

Yet another embodiment of the present invention provides a method for processing a substrate comprising flowing an inlet gas flow of one or more processing gases to an inlet opening formed through a blocker plate, and dividing the inlet gas flow to a first flow portion and a second flow portion into a gas distribution volume using a mini blocker plate disposed over the inlet opening of the blocker plate, wherein the mini blocker plate is disposed at a distance away from the blocker plate so that a gap is formed between the blocker plate and the mini blocker plate, the mini blocker plate has a plurality of through holes formed in a central region facing the inlet opening of the blocker plate, the first flow portion flows through the gap and is substantially parallel to the blocker plate, and the second flow portion flows through the plurality of through holes in the mini blocker plat.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 schematically illustrates a sectional side view of a plasma processing chamber in accordance with one embodiment of the present invention.

FIG. 2 is a partial schematic sectional view of a processing chamber having a mini blocker plate assembly in accordance with one embodiment of the present invention.

FIG. 3 is a schematic isometric view of a mini blocker plate assembly in accordance with one embodiment of the present invention.

FIG. 4 is a schematic isometric view of a mini blocker plate in accordance with one embodiment of the present invention.

FIGS. 5A and 5B are schematic sectional view and top view of a standoff spacer in accordance with one embodiment of the present invention.

FIG. 6 is a plot showing improvement in uniformity of crystalline fraction in a solar panel fabricated in a processing chamber having a blocker assembly in accordance with embodiments of the present invention.

FIGS. 7A and 7B are schematic top and side views respectively of a mini blocker plate in accordance with another embodiment.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

Embodiments of the present invention generally relates to a method and apparatus for delivering processing gas to a processing chamber for processing substrates, such as semiconductor substrates, solar panel substrates, liquid crystal display (LCD) substrates, and other large area substrates. Particularly, embodiments of the present invention relate to using a mini blocker plate assembly at a gas inlet opening of a blocker plate to improve uniformity. In one aspect, the mini blocker plate assembly of the present invention increases process uniformity across the entire substrate and reduces low flow near the gas inlet opening of the blocker plate. In another aspect, the mini blocker plate assembly of the present invention allows uniformal process/deposition at higher flow rate, thus enabling medium deposition rate and high deposition rate in depositing microcrystalline silicon.

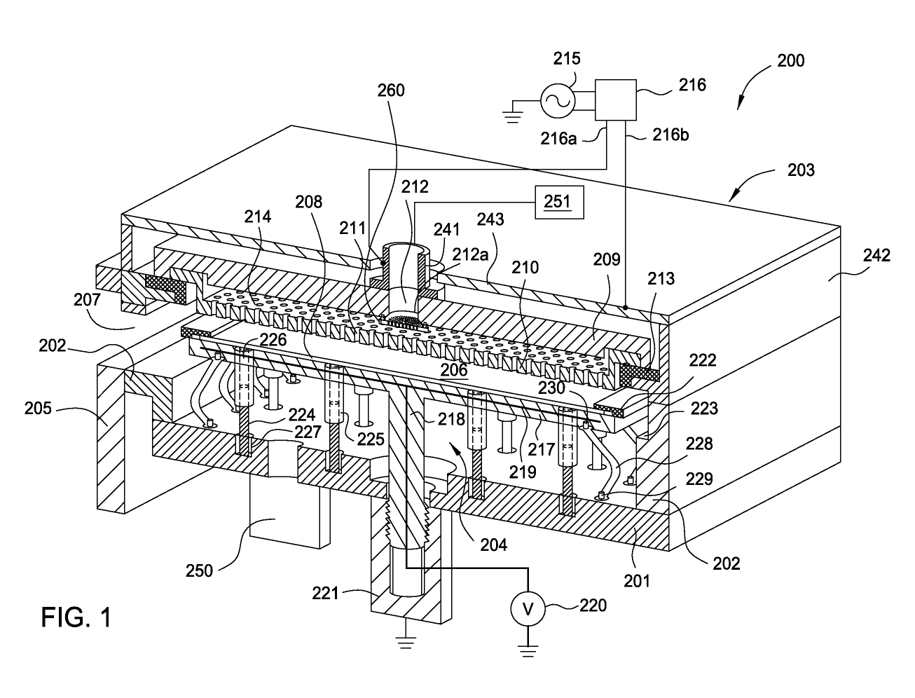

FIG. 1 schematically illustrates a sectional side view of a plasma processing chamber 200 in accordance with one embodiment of the present invention.

The plasma processing chamber 200 comprises a chamber bottom 201, sidewalls 202, and a lid assembly 203. The chamber bottom 201, sidewalls 202, and the lid assembly 203 define a processing volume 206. A substrate support assembly 204 is disposed in the processing volume 206. An opening 207 is formed through one side of the sidewalls 202. The opening 207 is configured to allow passages of substrate 208. A slit valve 205 is coupled to the sidewall 202 and configured to close the opening 207 during processing.

The lid assembly 203 is supported by the sidewalls 202 and can be removed to service the interior of the plasma processing chamber 200. The lid assembly 203 comprises an outer lid 242, a lid cover plate 243, a backing plate 209, a gas distribution plate 210, a gas conduit 241, and an isolator 213.

The backing plate 209 and the gas distribution plate 210 are disposed substantially parallel to each other forming a gas distribution volume 214 therebetween. The backing plate 209 and gas distribution plate 210 are configured to distribute a processing gas to the processing volume 206. The backing plate 209 and the gas distribution plate 210 are typically fabricated from aluminum. The isolator 213 is disposed on the sidewalls 202 and configured to electrically isolate the side walls 202 from the gas distribution plate 210 and the backing plate 209. The lid cover plate 243 is supported by the outer lid 242, and electrically connected to the sidewalls 202.

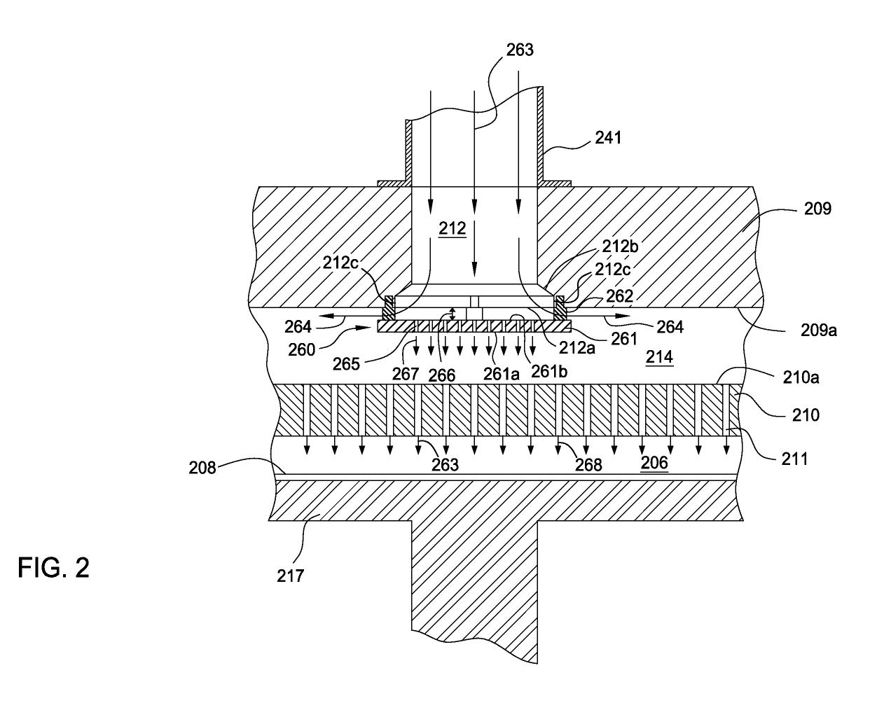

A through hole 212 is formed through the backing plate 209. The through hole 212 connects the gas distribution volume 214 to a gas source 251 the gas conduit 241. The gas source 251 is configured to provide one or more processing gases. The through hole 212 opens to the gas distribution volume 214 at an opening 212a. A mini blocker plate assembly 260 is disposed over the opening 212a. The mini blocker plate assembly 260 is configured to direct gas flow from the through hole 212 across the gas distribution volume 214 to enable processing gases substantially even distributed in the gas distribution volume 214 and eventually evenly distributed in the processing volume 206. The mini blocker plate assembly 260 is further described in FIG. 2.

The gas distribution plate 210 has a perforated area substantially corresponding to a processing area of a substrate 208 disposed on the substrate support assembly 204. A plurality of holes 211 are formed through the gas distribution plate 210 and provide fluid communication between the gas distribution volume 214 and the processing volume 206. The perforated area of the gas distribution plate 210 is configured to provide a uniform distribution of gases passing through the gas distribution plate 210 into the processing volume 206.

In one embodiment, the gas distribution plate 210, the backing plate 209, and the mini blocker plate assembly 260 may be fabricated from metals or other comparably electrically conductive materials, for example, aluminum, stainless steel, or metal alloys.

The substrate support assembly 204 is centrally disposed within the processing volume 206 and supports the substrate 208 during processing. The substrate support assembly 204 generally comprises an electrically conductive support body 217 supported by a shaft 218 which extends through the chamber bottom 201. The support body 217 is generally polygonal in shape and covered with an electrically insulative coating over at least the portion of the support body 217 that supports the substrate 208. The insulative coating may also cover other portions of the support body 217. In one embodiment, the substrate support assembly 204 is normally coupled to a ground potential at least during processing.

The support body 217 may be fabricated from metals or other comparably electrically conductive materials, for example, aluminum. The insulative coating may be a dielectric material such as an oxide, silicon nitride, silicon dioxide, aluminum dioxide, tantalum pentoxide, silicon carbide or polyimide, among others, which may be applied by various deposition or coating processes, including, but not limited to, flame spraying, plasma spraying, high energy coating, chemical vapor deposition, spraying, adhesive film, sputtering and encapsulating.

In one embodiment, the support body 217 encapsulates at least one embedded heating element 219 configured to heat the substrate 208 during processing. In one embodiment, the support body 217 also comprises a thermocouple for temperature control. In one embodiment, the support body 217 may comprise one or more stiffening members comprised of metal, ceramic or other stiffening materials embedded therein.

The heating element 219, such as an electrode or resistive element, is coupled to a power source 220 and controllably heats the substrate support assembly 204 and substrate 208 positioned thereon to a predetermined temperature. Typically, the heating element 219 maintains the substrate 208 at a uniform temperature of about 150 to at least about 460 degrees Celsius during processing. The heating element 219 is electrically floating relative to the support body 217.

The shaft 218 extends from the support body 217 through the chamber bottom 201 and couples the substrate support assembly 204 to a lift system 221. The lift system 221 moves the substrate support assembly 204 between an elevated processing position and a lowered position that facilitates substrate transfer.

In one embodiment, the substrate support assembly 204 comprises a circumscribing shadow frame 222. The circumscribing shadow frame 222 is configured to prevent deposition or other processing on edges of the substrate 208 and the support body 217 during processing. The circumscribing shadow frame 222 rests on the substrate 208 and the support body 217 when the substrate support assembly 204 is in an elevated processing position. When the substrate support assembly 204 is in a lowered position for substrate transferring, the circumscribing shadow frame 222 rests above the substrate support assembly 204 on a step 223 formed on the sidewalls 202.

In one embodiment, the support body 217 has a plurality of pin holders 225 disposed therethrough and configured to direct a plurality of lifting pins 224. Each pin holder 225 has a through hole 226 formed therein. The through hole 226 opens to an upper surface of the support body 217. Each pin holder 225 is configured to receive one lifting pin 224 from a lower opening of the through hole 226. Each lifting pin 224 extends upward from a recess 227 formed in the chamber bottom 201. As the support body 217 lowers along with the plurality of pin holders 225, the plurality of lifting pins 224 poke through the through holes 226 and pick up the substrate 208. The substrate 208 is then separated from the support body 217 allowing a substrate handler to transfer the substrate 208 out of the plasma processing chamber 200.

An RF power source 215 is used to generate plasma in the processing volume 206. In one embodiment, an impedance matching circuit 216 is coupled to the RF power source 215. A first output 216a of the impedance matching circuit 216 is connected with the gas distribution plate 210, and a second output 216b of the impedance matching circuit 216 is connected with the substrate support assembly 204, thus, applying a RF power between the processing gas disposed between the gas distribution plate 210 and the substrate support assembly 204 and generating and sustaining a plasma for processing the substrate 208 on the substrate support assembly 204.

In one embodiment, the first output 216a of the impedance matching circuit 216 is connected with the gas distribution plate 210 via the gas conduit 241 and the backing plate 209. In one embodiment, the second output 216b is coupled to the chamber body, e.g. the sidewalls 202, or the lid cover plate 243.

In one embodiment, a plurality of RF returning straps 228 are connected between the support body 217 of the substrate support assembly 204 to the chamber bottom 201 which is connected to the second output 216b of the impedance matching circuit 216. The plurality of RF returning straps 228 provide an RF current return path between the support body 217 and the chamber bottom 201.

FIG. 2 is a partial schematic sectional view of the processing chamber 200 having a mini blocker plate assembly 260 in accordance with one embodiment of the present invention. The mini blocker plate assembly 260 comprises a mini blocker plate 261 having a surface area similar to a sectional area of the through hole 212 in the backing plate 209, and two or more standoff spacers 262 configured to position the mini blocker plate 261 in a distance away from the backing plate 209 near the opening 212a of the through hole 212.

The mini blocker plate 261 may be a circular plate, or a plate has a shape substantially similar to the sectional shape of the through hole 212. The mini blocker plate 261 may be slightly larger than the opening 212a of the through hole 212. The mini blocker plate 261 has a plurality of through holes 265 formed through a central region. The plurality of through holes 265 is configured to allow a portion of gas from the through hole 212 in the backing plate 209 to enter the gas distribution volume 214 along a vertical direction.

In one embodiment, the mini blocker plate 261 may be fabricated from metals or other comparably electrically conductive materials, for example, aluminum, stainless steel, or metal alloys. In one embodiment, a lower surface 261a facing the gas distribution plate 210 may have a smooth finish, such as a mirror finish of about 2 microinches.

The standoff spacers 262 are disposed between the backing plate 209 and the mini blocker plate 261 to form a gap 266 between an upper surface 261b of the mini blocker plate 261 and a lower surface 209a of the backing plate 209. In one embodiment, the standoff spacers 262 may be cylindrical columns. In another embodiment, the standoff spacers 262 may have a streamlined profile, or an aero dynamic shape, to reduce turbulence in the gas flow.

In one embodiment, the through hole 212 may have a fared portion 212b near the opening 212a to reduce turbulence. In one embodiment, a recess 212c may be formed near the opening 212a providing a flat surface for mounting the standoff spacers 262 and the mini blocker plate 261 to the backing plate 209.

In one embodiment, the standoff spacers 262 may be columns extending from the upper surface 261b of the mini blocker plate 261. The standoff spacers 262 and the mini blocker plate 261 may be mounted to the backing plate 209 using suitable mounting methods, such as using screws.

In one embodiment, the plurality of through holes 211 in the gas distribution plate 210 may occupy a processing region large of about 6 square meters for processing substrates up to 2.6 meters by 2.2 meter in size. The backing plate 209 is substantially similar in size to the gas distribution plate 210 and the through hole 212 is located near a geometrical center of the backing plate 209. In one embodiment, the through hole 212 is about 5 inches in diameter and the mini blocker plate 261 is slightly larger in diameter than the through hole 212, for example with a diameter between about 5.5 inches to about 6.5 inches. In one embodiment, the mini blocker plate 261 is about 5.8 in diameter for covering a through hole about 5 inches in diameter. In one embodiment, the mini blocker plate 261 has a thickness between about 0.1 inches to about 0.3 inches. In one embodiment, the mini blocker plate 261 is about 0.18 inch thick.

In one embodiment, the gap 266 (between the backing plate 209 and the mini blocker plate 261) is between about 0.15 inches to about 0.5 inches. In one embodiment, the gap 266 is about 0.25 inches. In one embodiment, a distance between the lower surface 261a of the mini blocker plate 261 and an upper surface 210a of the gas distribution plate 210 is between about 0.3 inches to about 1.0 inches. In one embodiment, the distance between the lower surface 261a of the mini blocker plate 261 and an upper surface 210a of the gas distribution plate 210 is about 0.6 inches.

In one embodiment, the through holes 265 are evenly distributed across a central region of the mini blocker plate 261. In one embodiment, each through hole 265 has a diameter of between about 0.05 inch to about 0.2 inch. In one embodiment, each through hole has a diameter of about 0.1 inch.

As shown in FIG. 2, the mini blocker plate 261 substantially blocks the majority of a vertical downward gas flow 263 from the through hole 212 and generates substantially horizontal flows 264, which are substantially parallel to the backing plate 209 and the gas distribution plate 210, expanding to the entire gas distribution volume 214. A small portion of the vertical downward gas flow 263 goes through the plurality of through holes 265 in the mini blocker plate 261 and becomes a center gas flow 267 to provide a supply of processing gas to the region near the through holes 212 in the gas distribution volume 214.

In one embodiment, the ratio between gas flow 264 and the gas flow 267 is set to allow substantially uniform flow rate among flows 268 distributed across the gas distribution plate 210 including areas right underneath the through hole 212 and the mini blocker plate 261. In one embodiment, the ratio between the gas flow 264 and the gas flow 267 may be adjusted by adjusting the gap 266 between the mini blocker plate 261 and the backing plate 209. Other factors, such as the sizes of the through hole 212 in the backing plate 209, the size of the mini blocker plate 261, the size and density of the plurality of through holes 265 in the mini blocker plate 261, the flow rate of the inlet gas flow 263, the pressure in the processing volume 206, and the properties of the process gas, may also affect the ratio between the gas flows 264 and 267 and be adjusted to achieve uniform gas distribution if necessary.

Mini blocker plate assemblies according to embodiments of the present invention, such as the mini blocker plate assembly 260 described above, have several advantages comparing to the state-of-the art blocker assembly. In one aspect, the mini blocker plate assembly of the present invention increases process uniformity across the entire substrate and reduces low flow near the gas inlet opening of the blocker plate. In another aspect, the mini blocker plate assembly of the present invention allows uniformal process/deposition at higher flow rate, thus allows higher deposition rate, reduces process time and increases efficiency. For example, in the case of depositing microcrystalline silicon, processing chambers with the mini blocker plate assembly of the present invention have proven to have increased uniformity for medium deposition rate (MDR at about 400 Å/minute), and suitable for performing high deposition rate (HDR, deposition rate greater than 400 Å/minute) process.

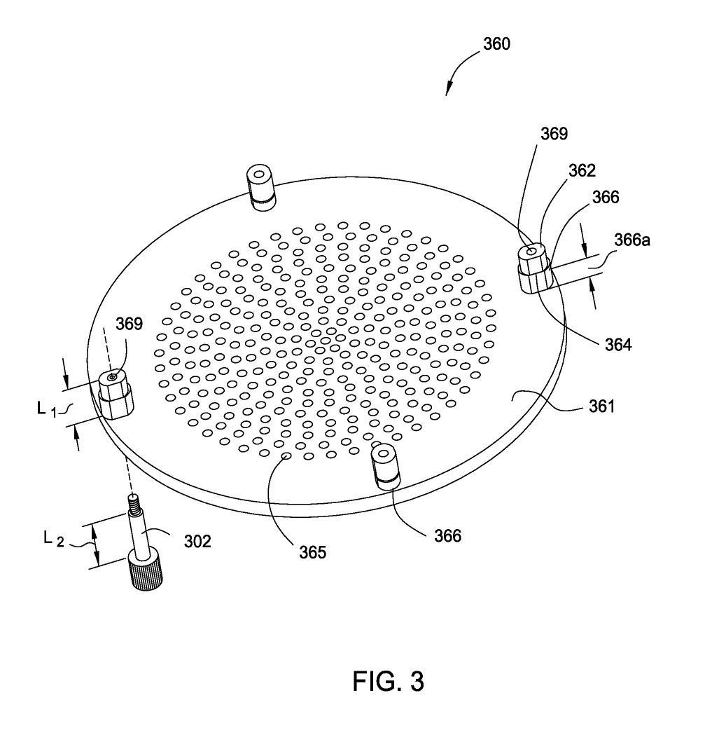

FIG. 3 is a schematic isometric view of a mini blocker plate assembly 360 in accordance with one embodiment of the present invention. The mini blocker plate assembly 360 having a plate body 361 and two or more standoff spacers 362 formed as one body. A plurality of through holes 365 are formed in a central region of the plate body 361.

The standoff spacers 362 are columns extending perpendicularly from one side of the plate body 361 near a periphery of the plate body 361. In one embodiment, the standoff spacers 362 are evenly distributed along the edge of the plate body 361. An at least partially threaded hole 369 is formed in through each standoff spacer 362 and the plate body 361 to allow mounting of the mini blocker plate assembly 360 using screws 302, one of which is shown in FIG. 3. In one embodiment, the screw 302 may be a shoulder screw having a shoulder length L₂ that is longer than a combined length L₁ of height of the standoff spacer 362 and the thickness of plate body 361. Thus, when the shoulder of screw 302 is inserted through a hole 304 of the standoff spacer 362 and the screw 302 engaged with a mating threaded hole formed in the backing plate 209, the standoff spacer 362 is not pressed against the backing plate 209, allowing a gap to be defined therebetween. This allows the standoff spacer 362 and plate body 361 to hang from the backing plate 209 when in use, thereby allowing the mini blocker plate assembly 360 to thermally expand and contract without rubbing against the backing plate 209, thereby avoiding generation of undesirable particles.

In one embodiment, the standoff spacers 362 have stream line profiles 364 to allow passing of gas flow with reduced turbulence. In one embodiment, the standoff spacers 362 may be narrower at the direction facing the gas flow than at the direction along the gas flow. In one embodiment, each standoff spacer 362 may have a base 366 with a height of 366a for forming the gap of at a height of 366a with a blocker plate.

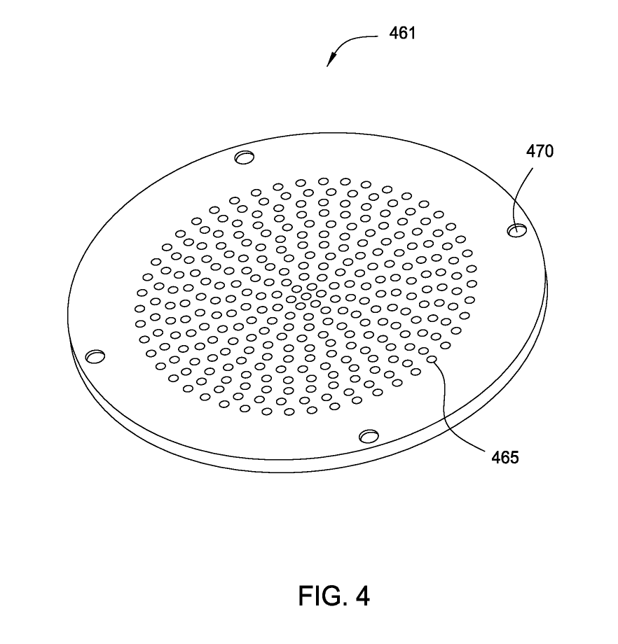

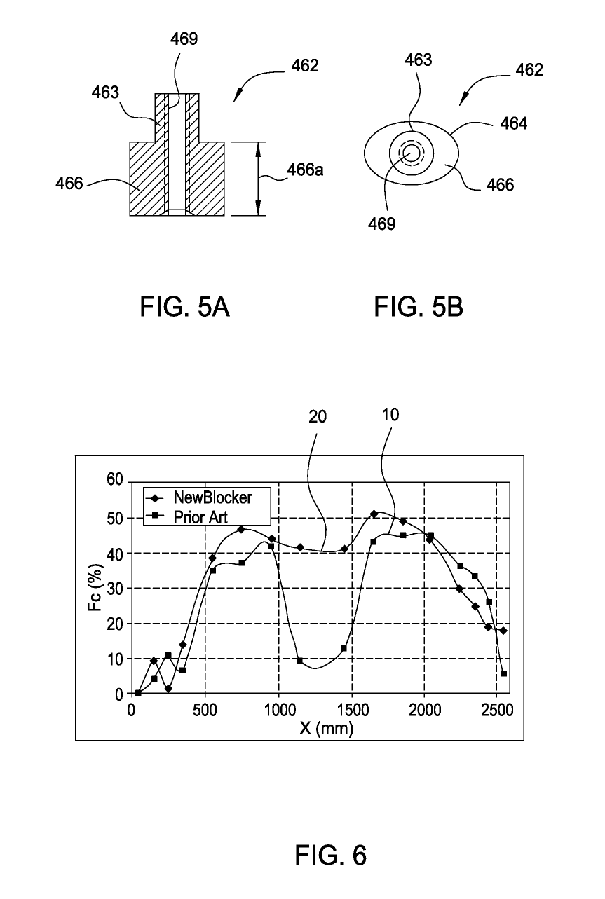

FIG. 4 is a schematic isometric view of a mini blocker plate 461 in accordance with one embodiment of the present invention. FIGS. 5A and 5B are schematic sectional view and top view of a standoff spacer 462 in accordance with one embodiment of the present invention. The mini blocker plate 461 and the standoff spacers 462 form a mini blocker plate assembly in according to embodiment of the present invention.

The mini blocker plate 461 has a plurality of through holes 465 are formed in a central region of the mini blocker plate 461, and two or more mounting holes 470 formed near an edge region of the mini blocker plate 461.

The standoff spacer 462 is a column having a mounting hole 469. In one embodiment, the mounting hole 469 is at least partially threaded to allow mounting of the mini blocker plate 461 using screws. In one embodiment, the standoff spacer 462 may have a base 466 and a mounting extension 463. The base 466 has a height of 466a for forming the gap of at a height of 466a with a blocker plate.

In one embodiment, the base 466 of the standoff spacer 462 has a stream line profile 464 to allow passing of gas flow with reduced turbulence.

FIG. 6 is a plot showing improvement in uniformity of crystalline fraction in a solar panel fabricated in a processing chamber having a mini blocker assembly in accordance with embodiments of the present invention. The X axis indicates locations of sample points along a diagonal line on a solar panel substrate. The Y axis indicates crystalline fraction (Fc) of a microcrystalline silicon film at the sample points. Crystalline fraction is one of the indicators of a microcrystalline silicon film. In case of solar panels, the crystalline fraction usually relates to conversion efficiency of the solar panel. Because crystalline fraction is easier to obtain than conversion efficiency, crystalline fraction is commonly used in determining the quality of the solar panel.

Curve 10 illustrates crystalline fractions of a microcrystalline silicon film at sample points along a diagonal line of a solar panel substrate using a state of the art blocker plate assembly, which includes a plate disposed over the an inlet opening (such as the opening 212a of FIG. 1), where the plate has directed channels to redirect gas flow to substantially parallel to a distribution plate blow (such as the gas distribution plate 210) for even distribution. The state of the art blocker assembly does not provide a small portion of vertical flow for regions below the plate covering the opening. The microcrystalline silicon film is formed from silane and hydrogen by plasma enhanced chemical deposition. As shown in curve 10, sample points between 1000 mm to 1500 mm on the diagonal line, which are located in or near the region below a central gas inlet of the blocker plate, have significantly lower crystalline fraction than other sample points.

Curve 20 illustrates crystalline fractions of a microcrystalline silicon film at sample points along a diagonal line of a solar panel substrate using the mini blocker plate assembly in accordance with embodiment of the present invention. The same chemistry is used in forming the microcrystalline silicon films reflected in curves 10 and 20. As shown by curve 20, crystalline fractions at sample points between 1000 mm to 1500 mm on the diagonal line are increased and good uniformity of crystalline fraction is demonstrated within a working region (for example between 500 mm to 2000 mm).

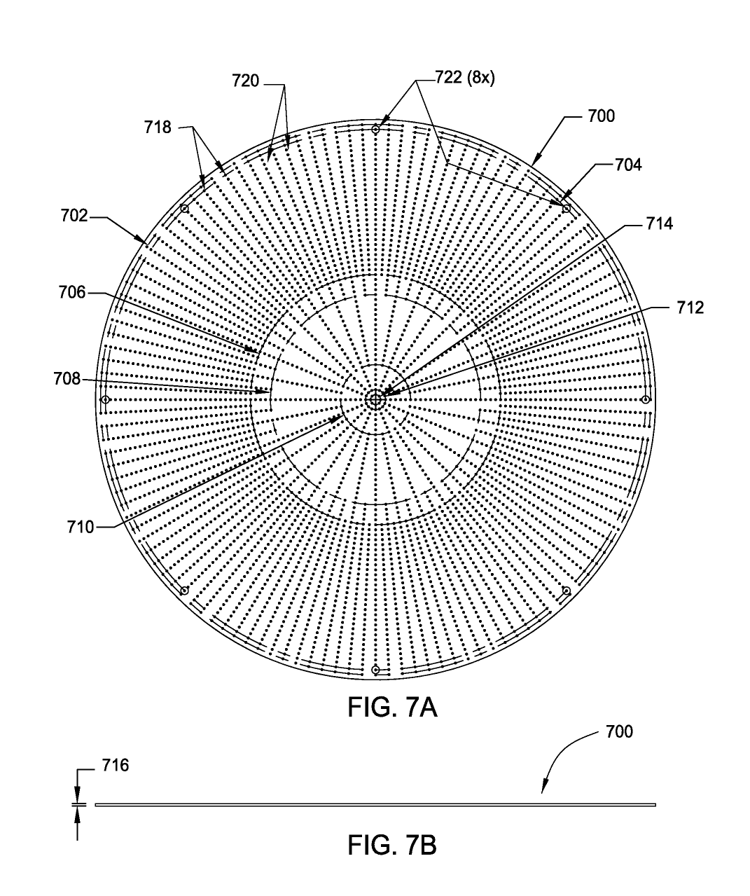

FIGS. 7A and 7B are schematic top and side views respectively of a mini blocker plate 700 in accordance with another embodiment. It is to be understood that while standoff spacers are not shown, the standoff spacers such as described above with regards to FIGS. 3 and 4 are applicable to the embodiment shown in FIGS. 7A and 7B. The mini blocker plate 700 may have a mirror polish of up to 2 microinches. The mini blocker plate 700 is generally about twice the diameter of the diameter of the hole 212 formed in the backing plate 209.

The mini blocker plate 700 includes a plurality of openings 718 that extend through the blocker plate body. In the embodiment shown in FIG. 7A, each of the openings 718 are substantially identical. The openings 718, however, are not identically arranged across the blocker plate body. The openings 718 are arranged in a polar array. In one embodiment, the openings 718 are arranged in a plurality of radially oriented lines 720 extending from an outermost diameter 702 in a direction towards the center 714. As the lines 720 converge towards the center 714 of the blocker plate body, the openings 718 in adjacent lines 720 are closer and closer together. Thus, one set of lines 720 extends from the outermost diameter 702 until it reaches a diameter 706 which is between about 6 and about 6.30 inches from the center 714. In one embodiment, the diameter 706 is greater than a diameter of the hole 212 formed in the backing plate 209. Another group of lines 720 extends from the outermost diameter 702 until reaching a diameter 708 that is between about 5 and about 5.30 inches from the center 714. Another group of lines 720 extends from the outermost diameter 702 until reaching a diameter 710 that is between about 1.50 and about 1.90 inches from the center 714. Finally, another group of lines 720 extends from the outermost diameter 702 until reaching a diameter 712 that is between about 0.30 to about 0.60 inches from the center 714.

The outer region of the mini blocker plate 700 defined between the diameter 706 and the outside diameter edge of the mini blocker plate 700 has an open area (defined as the area of openings 718 per unit area of the mini blocker plate 700) that is greater than an open area of the inner region radially inward of the diameter 706 to the center of the mini blocker plate 700. The smaller open area inward of the diameter 706 predominantly deflects gases exiting the opening 212a of the hole 212 perpendicular to the mini blocker plate 700 radially outward in the inner region, while the greater open area outward of the diameter 706 allows gases traveling parallel to the mini blocker plate 700 in the outer region to more readily pass through the openings 718 in the outer region, thus balancing the amount of gases passing through the openings 718 across the diameter of the mini blocker plate 700 and preventing high rate of passage through the center due to the predominantly perpendicular flow exiting the hole 212.

As shown in FIG. 7B, the mini blocker plate 700 has a thickness shown by arrows 716 to be between about 0.10 inches and about 0.14 inches. The standoff spacers (not shown) are coupled to the mini blocker plate 700 at mounting holes 722 that are at a diameter 704 of between about 13 inches to about 13.60 inches. In the embodiment shown in FIG. 7A, there are eight mounting holes 722 for coupling the standoff spacers to the mini blocker plate 700. The mounting holes 722 are equally spaced around diameter 704 and are linearly arranged within the lines 720. Each of the openings 718 have a diameter of between about 0.03 to about 0.05 inches while each location 722 has a diameter of between about 0.175 to about 0.190 inches. As the mounting holes 722 are positioned far outward (for example about 2 to 3 inches outward) of the hole 212, turbulence associated with the standoff spacers (not shown in FIGS. 7A-B) is greatly reduced as by locating the mounting holes 722 (and standoff spacers) well outward of the region where the flow exiting the hole 212 is deflected from a perpendicular to parallel orientation relative to the mini blocker plate 700, thereby contributing to uniformity of gas delivery through the gas distribution plate 210.

As shown in FIG. 7A, the number of openings 702 through the mini blocker plate body is significantly less inside of diameter 706. Diameter 706 of the mini blocker plate body aligns with the outer edge of the opening 212a in the backing plate 209 through which the gas exits the backing plate. The reason for fewer openings 702 inside of diameter 706 is because a significant amount of gas is concentrated between the center 714 and diameter 706 due to the alignment with the outer edge of the opening 212a in the backing plate 209. In order to ensure a more uniform distribution of gas throughout the plenum between the backing plate and the gas distribution plate 210, the gas needs to be restricted more in the area between diameter 706 and the center as compared to the area between diameter 706 and the outer edge of the mini blocker plate 700 to balance the high direction momentum and flow pressure of the gases exiting the opening 212a in the backing plate 209 relative to the gases passing over the outer region of the mini blocker plate 700.

Even though a plasma chamber and a plasma process are described above, the mini blocker assembly in accordance to embodiments of the present invention can be used in any processes where uniform delivery of processing gas is desired.

While the foregoing is directed to embodiments of the present invention, other and further embodiments of the invention may be devised without departing from the basic scope thereof, and the scope thereof is determined by the claims that follow.

What is claimed is:

1. A blocker plate assembly, comprising:
a mini blocker plate having a first side and a second side, wherein a plurality of through holes are formed from the first side to the second side in a central region of the mini blocker plate; and
two or more standoff spacers disposed on the first side of the mini blocker plate near an edge region of the mini blocker plate, wherein the mini blocker plate is configured to cover an inlet opening in a blocker plate, and the two or more standoff spacers are configured to position the first side of the mini blocker plate at a distance away from the blocker plate.

2. The blocker plate assembly of claim 1, wherein each of the standoff spacers has a mounting hole formed therethrough, and the mini blocker plate has two or more mounting holes corresponding to the two or more standoff spacers.

3. The blocker plate assembly of claim 2, wherein the standoff spacers are evenly distributed along the edge region of the mini blocker plate.

4. The blocker plate assembly of claim 2, wherein each of the standoff spacers has a stream line profile for reducing turbulence in a gas flow passing by.

5. The blocker plate assembly of claim 4, wherein each standoff spacer is narrower along the direction perpendicular to the gas flow than along the direction of the gas flow.

6. The blocker plate assembly of claim 2, wherein each of the standoff spacer comprises a base portion having a height equal to the distance.

7. The blocker plate assembly of claim 2, wherein the mini blocker plate and the two or more standoff spacers are formed from one body, and the two or more standoff spacers extend from the first side of the mini blocker plate.

8. The blocker plate assembly of claim 1, wherein the second side of the mini blocker plate has a mirror finish.

9. The blocker plate assembly of claim 1, wherein the mini blocker plate and the two or more standoff spacers are formed from aluminum.

10. An apparatus for delivering processing gas to a processing chamber, comprising:
a blocker plate having an inlet opening near a central region;
a distribution plate substantially parallel to the blocker plate, wherein the blocker plate and the distribution plate define a gas distribution volume therebetween, a first side of the distribution plate faces the blocker plate and a second side of the distribution plate faces a processing volume outside the distribution volume, and the distribution plate has a plurality of through holes connecting the gas distribution volume and the processing volume; and
a mini blocker plate assembly disposed in the gas distribution volume over the inlet opening of the blocker plate, wherein the mini blocker plate assembly comprises:
a mini blocker plate having a first side and a second side, wherein a plurality of through holes are formed from the first side to the second side in a central region of the mini blocker plate, and the first side of the mini blocker plate faces the inlet opening of the blocker plate; and
two or more standoff spacers disposed on the first side of the mini blocker plate near an edge region of the mini blocker plate, wherein the two or more standoff spacers position the first side of the mini blocker plate at a distance away from the blocker plate so that a gap is formed between the mini blocker plate and the blocker plate.

11. The apparatus of claim 10, wherein the mini blocker plate assembly is mounted to the blocker plate by tow or more crews through mounting holes formed in the mini blocker plate and the two or more standoff spacers.

12. The apparatus of claim 11, wherein each of the standoff spacers has a stream line profile for reducing turbulence in a gas flow passing by.

13. The apparatus of claim 12, wherein each standoff spacer is narrower along the direction perpendicular to the gas flow than along the direction of the gas flow.

14. The apparatus of claim 11, the second side of the mini blocker plate has a mirror finish.

15. The apparatus of claim 10, wherein the inlet opening of the blocker plate has a flared end facing the mini blocker plate assembly.

16. A method for processing a substrate, comprising:
flowing an inlet gas flow of one or more processing gases to an inlet opening formed through a blocker plate; and
dividing the inlet gas flow to a first flow portion and a second flow portion into a gas distribution volume using a mini blocker plate disposed over the inlet opening of the blocker plate, wherein the mini blocker plate is disposed at a distance away from the blocker plate so that a gap is formed between the blocker plate and the mini blocker plate, the mini blocker plate has a plurality of through holes formed in a central region facing the inlet opening of the blocker plate, the first flow portion flows through the gap and is substantially parallel to the blocker plate, and the second flow portion flows through the plurality of through holes in the mini blocker plate.

17. The method of claim 16, wherein dividing the inlet gas flow comprises adjusting a height of the gap to adjust the ratio of the first flow portion and the second flow portion.

18. The method of claim 17, wherein dividing the inlet gas flow comprises reducing flow turbulence using the standoff spacers having an aero dynamic profile.

19. The method of claim 17, further comprising flowing the first flow portion and the second flow portion from the distribution volume to a processing volume through a plurality of through holes in a distribution plate, wherein the distribution plate is substantially parallel to the blocker plate and the distribution volume is defined by the distribution plate and the blocker plate.

20. The method of claim 19, further comprising generating a plasma in the processing volume.
